(19) United States
(12) Patent Application Publication
(10) Pub. No.: US 2014/0281652 A1
(43) Pub. Date: Sep. 18, 2014

(54) DATA SYNCHRONIZATION ACROSS ASYNCHRONOUS BOUNDARIES USING SELECTABLE SYNCHRONIZERS TO MINIMIZE LATENCY

(71) Applicant: NVIDIA CORPORATION, Santa Clara, CA (US)

(72) Inventors: Tukaram Shankar Methar, Harmal (IN); Nilesh Acharya, Whitefield (IN); Jyotirmaya Swain, Marathalli (IN); Brian Lawrence Smith, Mountain View, CA (US)

(73) Assignee: NVIDIA CORPORATION, Santa Clara, CA (US)

(21) Appl. No.: 13/831,063

(22) Filed: Mar. 14, 2013

(51) Int. Cl. H03L 7/00; G06F 1/12

(52) U.S. Cl. CPC H03L 7/00; G06F 1/12
USPC 713/400; 327/144; 327/153

(57) ABSTRACT

A system and apparatus that include a selectable synchronizer circuit for synchronizing data across asynchronous boundaries are disclosed. The apparatus includes a unit associated with a first clock domain and a synchronizer sub-unit (SSU) coupled to the unit and associated with a second clock domain. The synchronizer sub-unit includes two or more synchronizers and selector logic configured to select one output of the two or more synchronizers.

### FIELD OF THE INVENTION

The present invention relates to data synchronization, and more particularly to synchronizers.

### BACKGROUND

Many digital systems have multiple clock domains. For example, a CPU may operate under one clock domain and a DRAM (dynamic random access memory) module may operate under a different clock domain. In some modern processors, multiple clock domains may be incorporated on the same silicon chip. In other words, a single processor may have multiple sub-units running on different clock domains. When signals are transmitted across asynchronous boundaries (i.e., from one clock domain to another clock domain), the signals must be synchronized to prevent metastability and synchronization failure. Metastability can be caused when a data signal transitions too close to the transition of a clock edge in the receiving circuit, which can cause the voltage at circuit elements in the receiving circuit to become metastable (i.e., taking a value between logic high and logic low that could register as either logic high or logic low).

Circuit designers traditionally design synchronizers in order to reliably sample signals transmitted between asynchronous circuits. A simple synchronizer consists of two flip-flops coupled in series, with the output of the first flip-flop connected to the input of the second flip-flop. The signal is connected to the input of the first flip-flop and both flip-flops are clocked using the clock domain of the receiving circuit. The output of the second flip-flop is delayed by up to two clock cycles of the receiving clock from the sampled input to the first flip-flop to allow time for the sampled signal to stabilize with the clock domain of the receiving circuit. This circuit is commonly referred to as a dual stage synchronizer. Additional stages (i.e., flip-flops) may be added to the circuit in order to increase the mean time between failures (MTBF) of the synchronizer to ensure that failures are highly unlikely to occur due to metastability. However, each additional stage in the synchronizer adds additional latency (i.e., clock cycles) between when the transmitter sends a signal and when the receiver can sample the signal.

Designers may design synchronizers according to specifications tailored to the most critical applications in the most extreme conditions. For example, a designer may ensure that the MTBF for a synchronizer circuit is 10,000 years when the circuit is operated at high frequency and extreme temperatures (e.g., 5 GHz at −40° F.). Ensuring high MTBF at extreme operating conditions may be required when an application for the device requires high reliability (e.g., processors used in pacemakers, defense systems, etc.). The result of designing synchronizers associated with high MTBF at extreme operating conditions may require synchronizers that have high latency (e.g., 5-stage synchronizers that have 5 cycles of latency). The high latency associated with such synchronizers may be detrimental to other applications that have a higher tolerance for failures (e.g., MTBF of 1 day) but require low latency. Thus, there is a need for addressing this issue and/or other issues associated with the prior art.

### SUMMARY

A system and apparatus that include a selectable synchronizer circuit for synchronizing data across asynchronous boundaries are disclosed. The apparatus includes a unit associated with a first clock domain and a synchronizer sub-unit (SSU) coupled to the unit and associated with a second clock domain. The synchronizer sub-unit includes two or more synchronizers and selector logic configured to select one output of the two or more synchronizers.

### BRIEF DESCRIPTION OF THE DRAWINGS

FIG. 1A illustrates a device that implements a selectable synchronizer circuit, in accordance with one embodiment;

FIG. 1B illustrates the SSU of FIG. 1A, in accordance with one embodiment;

FIG. 2 illustrates a technique for implementing clock synchronization via handshake signaling, in accordance with one embodiment;

FIG. 3A illustrates a dual-stage synchronizer, in accordance with one embodiment;

FIG. 3B illustrates a three-stage synchronizer, in accordance with one embodiment;

FIG. 3C illustrates a one-and-a-half-stage synchronizer, in accordance with one embodiment;

FIG. 4A illustrates a bypass circuit included in SSU to aid in properly transitioning between two synchronizers, in accordance with one embodiment;

FIG. 4B illustrates a delay sub-circuit, in accordance with one embodiment; and

FIG. 5 illustrates an exemplary system in which the various architecture and/or functionality of the various previous embodiments may be implemented.

### DETAILED DESCRIPTION

Synchronizer design may be determined based on the most critical application expected to be implemented using the circuit. While that specific application may need extremely high reliability at the cost of high latency, other less critical applications may benefit from lower latency synchronizers. High costs associated with manufacturing different parts for specific applications make designing different synchronizers for the myriad of different applications and operating conditions impractical. However, multiple synchronizers may be included in the design and the proper synchronizer for the application may be selected to provide the best combination of reliability and latency.

For example, a processor may be designed that includes two selectable synchronizers, a first lower latency, lower reliability dual-stage synchronizer and a second high latency, higher reliability N-stage synchronizer. For example, the N-stage synchronizer may be a three-stage synchronizer that provides higher reliability than the dual-stage synchronizer. The processor may be configured to use either the first synchronizer or the second synchronizer based on the particular application. For example, the second synchronizer may be selected in processors intended to be used in pacemakers, while the first synchronizer may be selected in processors intended to be used in a non-critical consumer electronic device such as a cellular phone.

FIG. 1A illustrates a device 100 that implements a selectable synchronizer circuit, in accordance with one embodiment. As shown in FIG. 1A, device 100 includes a first unit 101 associated with a first clock domain 105 (CLK_1) and a second unit 102 associated with a second clock domain 106 (CLK_2). The clock domains are asynchronous such that data transmitted between the sub-units should be synchronized to avoid issues due to metastability. Each of the sub-units (e.g., 101, 102) may include a synchronizer sub-unit (SSU) 110 that is configured to synchronize a data signal received by the SSU 110 to the clock domain associated with the respective unit.

It will be appreciated that SSU 110 may be included in device 100 external to units 101 and 102. Although SSU 110 is shown as included within units 101 and 102 in FIG. 1A, the SSU 110 may be implemented separate and distinct from each of the units as part of an asynchronous boundary interface.

FIG. 1B illustrates the SSU 110 of FIG. 1A, in accordance with one embodiment. As shown in FIG. 1B, SSU 110 includes a first synchronizer circuit 111 and a second synchronizer circuit 112. The data signal 116 received by the SSU 110 is connected to both the first synchronizer circuit 111 and the second synchronizer circuit 112. The first synchronizer circuit 111 and the second synchronizer circuit 112 are different types of synchronizers designed for different types of applications. For example, the first synchronizer circuit 111 may be a dual-stage synchronizer comprising two flip-flops clocked to the clock domain associated with the SSU 110 (e.g., CLK_1 105, CLK_2 106, etc.), and the second synchronizer circuit 112 may be a three-stage synchronizer comprising three flip-flops clocked to the same clock-domain. Although the first synchronizer circuit 111 only has a latency of two clock cycles, the MTBF of the first synchronizer circuit 111 may be insufficient for some applications. Therefore, the SSU 110 includes the second synchronizer circuit 112 for those critical applications that require more reliability.

The SSU 110 also includes selector logic 115 for selecting either the first synchronizer circuit 111 or the second synchronizer circuit 112. In one embodiment, the selector logic 115 is a multiplexor tied to the output of the first synchronizer circuit 111 and the second synchronizer circuit 112. The selector logic 115 receives a selector signal 118 that determines which synchronizer circuit (111 or 112) is configured to synchronize the data signal 116 with the asynchronous clock domain. As shown in FIG. 1B, if the first synchronizer circuit 111 is selected, then the output of the first synchronizer circuit 111 is connected to the output 117 of the SSU 110 and transmitted to the unit (e.g., 101, 102) coupled to the SSU 110. In contrast, if the second synchronizer circuit 112 is selected, then the output of the second synchronizer circuit 112 is connected to the output 117 of the SSU 110 and transmitted to the unit coupled to the SSU 110.

In one embodiment, the SSU 110 includes three or more synchronizers. For example, SSU 110 may include a first synchronizer 111, a second synchronizer 112, a third synchronizer (not explicitly shown), and a fourth synchronizer (not explicitly shown). The four synchronizers may correspond to a half-stage synchronizer, a dual-stage synchronizer, a three-stage synchronizer, and a four-stage synchronizer. The selector logic 115 may be a 4 channel multiplexor with a 2-bit selection code that is used to select one of the four synchronizers. In general, the SSU 110 may include N separate and distinct synchronizers and selector logic 115 to select one of the N synchronizers.

The SSU 110 may be configured either statically or dynamically. In one embodiment, the SSU 110 is configured statically in order to use one of the synchronizers included in the SSU 110. While the design of the device does not change, the selection of which particular synchronizer included in the SSU 110 may be changed in order to configure the device per the desires of the user. For example, the SSU 110 may be configured by blowing a fuse that disables one or more synchronizers in the SSU 110. The fuse may cause either a 0 or a 1 to be coupled to the selector signal 118 which selects which synchronizer to be used.

In another embodiment, the SSU 110 is configured dynamically. A register may store a bit which configures SSU 110 to use one of the synchronizers (e.g., 111, 112) based on the state of the register. The register value may be set when the device 100 is first powered up. In yet another embodiment, the SSU 110 is configured dynamically by an application program or based on one or more parameters. The device 100 may monitor various conditions to determine the parameters, such as the classification of the device 100 in response to testing based on the relative distribution of the device within the process spread, the frequency of one or more clock domains, the temperature of the device 100 (via temperature sensors), the supply voltage for the device, and then the device 100 may dynamically configure the SSU 110 based on the current conditions that exist on the device 100. For example, the device 100 is configured to use the first synchronizer 111 when the temperature on the device is less than 50° C., and the device 100 is configured to use the second synchronizer 112 when the temperature on the device is greater than or equal to 50° C.

FIG. 2 illustrates a technique for implementing clock synchronization via handshake signaling, in accordance with one embodiment. As shown in FIG. 2, the device 200 is similar to device 100 except the signals transmitted between unit 101 and unit 102 implement handshake signaling. As shown in FIG. 2, unit 101 is a transmitter unit and unit 102 is a receiver unit. In order to transmit a data signal between the transmitter unit 101 and the receiver unit 102, the transmitter unit 101 drives the data signal (Data) on the data bus and then asserts the request signal (Req). The asynchronous request signal is coupled to the SSU 110 in the receiver unit 102. The transmitter unit 101 maintains the data signal until the receiver unit 102 asserts the acknowledge signal (Ack). The data bus does not need to be connected to the SSU 110 because a race condition between the data bus and the request signal should be avoided.

Because the SSU 110 delays the receipt of the asynchronous request signal, the receiver unit 102 can safely sample the data signal on the data bus once the delayed request signal is asserted. After the receiver unit 102 has sampled the data signal, the receiver unit 102 can assert the acknowledge signal, which is transmitted back to the transmitter unit 101. The acknowledge signal is routed through the SSU 110 included in the transmitter unit 101. Once the transmitter unit 101 receives the delayed acknowledge signal, the transmitter unit 101 can reset the request signal and change the data on the data bus. Once the receiver unit 102 receives the reset request signal, the receiver unit 102 can reset the acknowledge signal and the data transmission is complete.

The handshaking technique described above is associated with high latency due to the delay associated with the synchronized handshake signals. In other embodiments, other techniques for transmitting signals across asynchronous boundaries may be implemented. For example, latency of the handshake signaling technique described above may be reduced by toggling the request signals and acknowledge signals such that the signals don't have to be reset between each data transmission.

FIG. 3A illustrates a dual-stage synchronizer 310, in accordance with one embodiment. As shown in FIG. 3A, a data signal 301 is received at an input of a first flip-flop 311. The first flip-flop 311 is clocked by a synchronized clock signal (CLK_S) 305. The output of the first flip-flop 311 is connected to the input of a second flip-flop 312 that is clocked by the synchronized clock signal 305. The output of the second flip-flop 312 is a synchronized data signal (DATA_S) 302. The synchronized data signal 302 is synchronized with the clock domain associated with the synchronized clock signal 305.

The output of the first flip-flop 311 may be metastable in the case where the rising edge of the synchronized clock signal 305 corresponds to a transition of the data signal 301. In other words, the voltage potential of the first flip-flop 311 may be somewhere between the voltage potential corresponding to digital low or digital high. The voltage potential of the output of the first flip-flop 311 may resolve to either digital high or digital low after a short time, which is then transitioned to the output of the second flip-flop 312 at the next rising edge of the synchronized clock signal 305. Because the output of the first flip-flop 311 may have been metastable after the first transition, the data signal 301 must be maintained at the input of the first flip-flop 311 for multiple clock cycles. At the first rising edge of the synchronized clock signal 305, the output of the first flip-flop 311 may be metastable. However, at the second rising edge of the synchronized clock signal 305, the output of the first flip-flop may be resolved to the correct value of the data signal 301. At the next rising edge of the synchronized clock signal 305, the output of the first flip-flop 311 is transitioned to the output of the second flip-flop 312 and coupled to the synchronized data signal 302. Thus, the data signal 301 is synchronized with the new clock domain after a delay of two clock cycles.

FIG. 3B illustrates a three-stage synchronizer 320, in accordance with one embodiment. As shown in FIG. 3B, a data signal 301 is received at an input of a first flip-flop 321. The first flip-flop 321 is clocked by a synchronized clock signal (CLK_S) 305. The output of the first flip-flop 321 is connected to the input of a second flip-flop 322 that is clocked by the synchronized clock signal 305. The output of the second flip-flop 322 is connected to the input of a third flip-flop 323 that is clocked by the synchronized clock signal 305. The output of the third flip-flop 323 is a synchronized data signal (DATA_S) 302. The synchronized data signal 302 is synchronized with the clock domain associated with the synchronized clock signal 305.

It will be appreciated that the output of the third flip-flop 323 is synchronized at a greater reliability than the output of the second flip-flop 312 in the dual-stage synchronizer 310 of FIG. 3A. Even with the dual-stage synchronizer 310, the synchronized data signal 302 could be metastable if the metastable output of the first flip-flop 311 propagates to the output of the second flip-flop 312 before the metastable output of the first flip-flop 311 has a chance to settle. The additional flip-flop stage in the three-stage synchronizer 320 of FIG. 3B reduces the probability that the metastable output propagates to the synchronized data signal 302. In other words, generally speaking, the more stages in the synchronizer, the larger the MTBF of the synchronizer and the more reliable the synchronized output. In yet other embodiments, additional stages may be added to implement N-stage synchronizers having N flip-flops.

FIG. 3C illustrates a one-and-a-half-stage synchronizer 330, in accordance with one embodiment. As shown in FIG. 3C, a data signal 301 is received at an input of a first flip-flop 331. The first flip-flop 331 is clocked by an inverted synchronized clock signal (CLK_S) 305. The output of the first flip-flop 331 is connected to the input of a second flip-flop 332 that is clocked by the synchronized clock signal 305. In other words, the input of the first flip-flop 331 is transitioned to the output of the first flip-flop 331 at the falling edge of the synchronized clock signal 305, and the input of the second flip-flop 332 is transitioned to the output of the second flip-flop 332 at the rising edge of the synchronized clock signal 305. The output of the second flip-flop 332 is a synchronized data signal (DATA_S) 302. The synchronized data signal 302 is synchronized with the clock domain associated with the synchronized clock signal 305. The one-and-a-half-stage synchronizer 330 has half the time for the metastable output of the first flip-flop 331 to settle as compared to the dual-stage synchronizer 310 using the same frequency synchronized clock signal 305.

The synchronizers described in FIGS. 3A through 3C are exemplary synchronizers that may be implemented in the SSU 110. It will be appreciated that, in other embodiments, other synchronizers may be implemented in SSU 110, including special synchronizers with additional logic in addition to or in lieu of the flip-flop stages described above. Any synchronizers, including specialized synchronizers, may be included within the SSU 110.

FIG. 4A illustrates a bypass circuit 400 included in SSU 110 to aid in properly transitioning between two synchronizers, in accordance with one embodiment. As shown in FIG. 4A, the bypass circuit 400 includes a delay sub-circuit 401 and a multiplexor 402. The data signal 116 is coupled to one input of the multiplexor 402 and the input of the delay sub-circuit 401. The output of the delay sub-circuit 401 is coupled to another input of the multiplexor 402. The function of the bypass circuit 400 is to aid in transitioning between the different synchronizers (e.g., 111, 112) of the SSU 110. Because the different synchronizers may be associated with different latency, the SSU 110 may need to delay the input signal 116 being applied to a different synchronizer during the transition.

For example, the first synchronizer 111 is being used by a processor to sample an asynchronous signal 116 and the first synchronizer 111 has a latency of 5 clock cycles. The processor may be configured to dynamically transition from using the first synchronizer 111 to a second synchronizer 112 that has a latency of 2 clock cycles. If the processor transitions immediately to the second synchronizer 112, the data at the output of the second synchronizer 112 will be three clock cycles ahead of the data at the output of the first synchronizer 111. Thus, the processor may need to configure the bypass circuit 400 to switch to the output of the delay sub-circuit 401 such that the data arriving at the second synchronizer 112 is properly aligned with the data being output by the first synchronizer 111 at the transition. Without the delay circuit 400, the output of the SSU 110 may miss data on the asynchronous data signal 116.

It will be appreciated that the bypass circuit 400 is only necessary when the processor is dynamically configured to use two or more synchronizers during operation. If the processor is only configured to use one synchronizer for the entire time that the processor is operational, such as selecting one of the plurality of synchronizers during the boot-sequence, and may not switch to a different synchronizer while the processor is in operation, then the bypass circuit 400 is not necessary for proper operation of the SSU 110. In addition, the functionality of the bypass circuit 400 may not be necessary if the transition between the synchronizers is only performed while the data signal is idle (i.e., no data is being transferred between the asynchronous boundary. Various protocols may be implemented that monitor the state of the asynchronous data input signal 116. If the data input signal 116 has been idle for a number N clock cycles, then the SSU 110 may be allowed to transition from one synchronizer to another.

FIG. 4B illustrates a delay sub-circuit 401, in accordance with one embodiment. As shown in FIG. 4B, the delay sub-circuit 401 includes a plurality of flip-flops (e.g., 411, 412, 413, 414, 415, and 416). The flip-flops delay the asynchronous data input signal 116 by a number of clock cycles (CLK) in the time domain of the transmitting unit, thereby acting as a short history buffer for the input signal 116. By configuring the multiplexor 402 to switch from the asynchronous data input signal 116 to the output of the delay sub-circuit 401, the bypass circuit 400 is capable of replaying a delayed portion of the data input signal 116 to the newly selected synchronizer in the SSU 110.

In one embodiment, when the delay sub-circuit 401 is utilized when switching between synchronizers, the prior state of the data input signal 116 should be maintained while the previously selected synchronizer empties. For example, when a three-stage synchronizer is emptied the state of the data input signal 116 is maintained for at least three clock cycles in the receiving clock domain so that any data being transitioned through the synchronizer reaches the end of the chain of flip-flops. While this is happening, the delay sub-circuit 401 may be storing the state of the data input signal 116 in order to replay the state of the data input signal 116 when the new synchronizer is selected. Although not shown explicitly, a latch circuit or other circuit element may be implemented within the bypass circuit 400 in order to maintain the previous state of the data input signal 116 at the input of the synchronizer circuits while a transition between two synchronizers is being effectuated. The previous state of the data input signal may be selected using an additional multiplexor while the transition is effectuated. Alternatively, transitioning between two synchronizers may be delayed until the delay sub-circuit 401 indicates a constant state of an input signal 116 for a minimum number of clock cycles. In other words, the chain of flip-flops in the delay sub-circuit 401 may be sampled (e.g., using logic gates) to determine whether the outputs of all of the flip-flops are similar. If all of the outputs are similar, then a transition may be effectuated because the output state of all of the synchronizers is ensured to be the same. Transitions can be controlled via software or hardware.

Once the delay sub-circuit 401 has been selected to route a delayed version of the data input signal 116 to the synchronizers, the multiplexor 402 should not select the data input signal 116 until the data input signal 116 has remained at the same state for a given number of clock cycles (e.g., such that the chain of flip-flops in the delay sub-circuit 401 all have the same output). It will be appreciated that a number of different techniques may be implemented to ensure proper transitions between two synchronizers including deactivating the interface (i.e., preventing signals from being transmitted between the two clock domains) during the transition, using a history buffer to determine when it is safe to transition (i.e., the history buffer indicates the input signal has remained at the same state for a time greater than or equal to the maximum latency of the synchronizers), using a bypass chain to save transitions while a constant state is allowed to propagate through the synchronizers (as described above), or other possible techniques. Each of the techniques described above may be implemented when dynamically transitioning between two of the synchronizers in the SSU 110.

In another embodiment, the delay sub-circuit 401 may implement other components in order to effectuate a delayed version of the data input signal 116. For example, the delay sub-circuit 401 may sample the data input signal 116 in the transmitting clock domain and store the sample signal in an asynchronous FIFO. Other circuits that effectuate a delay of the data input signal 116 are contemplated as within the scope of the present disclosure.

It should be noted that, while various optional features are set forth herein in connection with the SSU 110, such features are for illustrative purposes only and should not be construed as limiting in any manner. In one embodiment, the SSU 110, described above, may be implemented in a system 500 having multiple components operating across asynchronous boundaries.

FIG. 5 illustrates an exemplary system 500 in which the various architecture and/or functionality of the various previous embodiments may be implemented. As shown, a system 500 is provided including at least one central processor 501 that is connected to a communication bus 502. The communication bus 502 may be implemented using any suitable protocol, such as PCI (Peripheral Component Interconnect), PCI-Express, AGP (Accelerated Graphics Port), HyperTransport, or any other bus or point-to-point communication protocol(s). The system 500 also includes a main memory 504. Control logic (software) and data are stored in the main memory 504 which may take the form of random access memory (RAM).

The system 500 also includes input devices 512, a graphics processor 506, and a display 508, i.e. a conventional CRT (cathode ray tube), LCD (liquid crystal display), LED (light emitting diode), plasma display or the like. User input may be received from the input devices 512, e.g., keyboard, mouse, touchpad, microphone, and the like. In one embodiment, the graphics processor 506 may include a plurality of shader modules, a rasterization module, etc. Each of the foregoing modules may even be situated on a single semiconductor platform to form a graphics processing unit (GPU).

In the present description, a single semiconductor platform may refer to a sole unitary semiconductor-based integrated circuit or chip. It should be noted that the term single semiconductor platform may also refer to multi-chip modules with increased connectivity which simulate on-chip operation, and make substantial improvements over utilizing a conventional central processing unit (CPU) and bus implementation. Of course, the various modules may also be situated separately or in various combinations of semiconductor platforms per the desires of the user.

The system 500 may also include a secondary storage 510. The secondary storage 510 includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 504 and/or the secondary storage 510. Such computer programs, when executed, enable the system 500 to perform various functions. The memory 504, the storage 510, and/or any other storage are possible examples of computer-readable media.

In one embodiment, the architecture and/or functionality of the various previous figures may be implemented in the context of the central processor 501, the graphics processor 506, an integrated circuit (not shown) that is capable of at least a portion of the capabilities of both the central processor 501 and the graphics processor 506, a chipset (i.e., a group of integrated circuits designed to work and sold as a unit for performing related functions, etc.), and/or any other integrated circuit for that matter.

Still yet, the architecture and/or functionality of the various previous figures may be implemented in the context of a general computer system, a circuit board system, a game console system dedicated for entertainment purposes, an application-specific system, and/or any other desired system. For example, the system 500 may take the form of a desktop computer, laptop computer, server, workstation, game consoles, embedded system, and/or any other type of logic. Still yet, the system 500 may take the form of various other devices including, but not limited to a personal digital assistant (PDA) device, a mobile phone device, a television, etc.

Further, while not shown, the system 500 may be coupled to a network (e.g., a telecommunications network, local area network (LAN), wireless network, wide area network (WAN) such as the Internet, peer-to-peer network, cable network, or the like) for communication purposes.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

What is claimed is:

1. A apparatus, comprising:
a unit associated with a first clock domain; and
a synchronizer sub-unit (SSU) coupled to the unit and associated with a second clock domain, wherein the SSU includes two or more synchronizers and selector logic configured to select one output of the two or more synchronizers.

2. The apparatus of claim 1, wherein the two or more synchronizers include a first synchronizer associated with a first latency and a second synchronizer associated with a second latency, and wherein the first latency is less than the second latency.

3. The apparatus of claim 2, wherein the first synchronizer is a dual-stage synchronizer and the second synchronizer is a three-stage synchronizer.

4. The apparatus of claim 1, wherein the SSU further includes a bypass circuit that includes a delay sub-circuit and a multiplexor.

5. The apparatus of claim 4, wherein the SSU is configured to transition between two synchronizers when the delay sub-circuit indicates a constant state of an input signal for a minimum number of clock cycles.

6. The apparatus of claim 4, wherein the delay sub-circuit comprises a plurality of flip-flops.

7. The apparatus of claim 1, wherein the SSU is dynamically configured to select one output of the two or more synchronizers based on at least one parameter.

8. The apparatus of claim 7, wherein the at least one parameter comprises one or more of an intended use of the apparatus, a temperature, a supply voltage, a frequency, and a classification of the apparatus based on testing.

9. The apparatus of claim 1, wherein the SSU includes three or more synchronizers and the selector logic is configured to select one output of the three or more synchronizers.

10. The apparatus of claim 1, further comprising:
a second unit associated with the second clock domain; and
a second SSU coupled to the second unit and associated with the first clock domain.

11. The apparatus of claim 10, wherein the first unit and second unit implement a handshake signaling technique to synchronize a signal associated with the first clock domain with the second clock domain.

12. A system, comprising:
a processor that includes:
a unit associated with a first clock domain, and
a synchronizer sub-unit (SSU) coupled to the unit and associated with a second clock domain, wherein the SSU includes two or more synchronizers and selector logic configured to select one output of the two or more synchronizers.

13. The system of claim 12, wherein the two or more synchronizers include a first synchronizer associated with a first latency and a second synchronizer associated with a second latency, and wherein the first latency is less than the second latency.

14. The system of claim 13, wherein the first synchronizer is a dual-stage synchronizer and the second synchronizer is a three-stage synchronizer.

15. The system of claim 12, wherein the SSU further includes a bypass circuit that includes a delay sub-circuit and a multiplexor.

16. The system of claim 12, wherein the SSU is dynamically configured to select one of the two or more synchronizers based on at least one parameter.

17. The system of claim 16, wherein the at least one parameter comprises one or more of an intended use of the processor, a temperature, a supply voltage, a frequency, and a classification of the processor based on testing.

18. The system of claim 12, the system further comprising:
a second unit associated with the second clock domain; and
a second SSU coupled to the second unit and associated with the first clock domain.

19. The system of claim 12, wherein the processor comprises a graphics processing unit.

20. The system of claim 12, wherein the processor is included in a system-on-chip (SoC).
